(19) United States
(12) Patent Application Publication
(10) Pub. No.: US 2014/0106501 A1
(43) Pub. Date: Apr. 17, 2014

(54) METHOD AND APPARATUS FOR ELECTRODEPOSITION OF GROUP IIB-VIA COMPOUND LAYERS

(71) Applicant: Encoresolar, Inc., San Jose, CA (US)

(72) Inventor: Bulent M. BASOL, San Jose, CA (US)

(73) Assignee: Encoresolar, Inc., San Jose, CA (US)

(21) Appl. No.: 14/135,254

(22) Filed: Dec. 19, 2013

Related U.S. Application Data
(62) Division of application No. 13/345,012, filed on Jan. 6, 2012.

(51) Int. Cl. H01L 31/18

(52) U.S. Cl. CPC H01L 31/1828
USPC 438/95

(57) ABSTRACT

Methods and apparatus are described for electrodeposition of Group IIB-VIA materials out of electrolytes comprising Group IIB and Group VIA species onto surfaces of workpieces. In one embodiment a method of electrodeposition is described wherein the control of the process is achieved by measuring an initial value of the electrodeposition current at the beginning of the process and adding Group VIA species into the electrolyte to keep the electrodeposition current substantially constant, such a within +/−10% of the initial value throughout the deposition period. In another embodiment an apparatus comprising multiple deposition chambers are described, each deposition chamber containing an anode and a workpiece, and wherein two thirds of the deposition chambers within the apparatus contain anodes comprising a substantially pure Group VIA element in their composition, and the rest of the deposition chambers contain anodes free from any Group VIA element in their composition.

### FIELD OF THE INVENTION

The present invention relates to methods and apparatus for forming thin films of Group IIB-VIA compound semiconductor films, specifically CdTe films, for radiation detector and photovoltaic applications.

### BACKGROUND OF THE INVENTION

Solar cells and modules are photovoltaic (PV) devices that convert sunlight energy into electrical energy. The most common solar cell material is silicon (Si). However, lower cost PV cells may be fabricated using thin film growth techniques that can deposit solar-cell-quality polycrystalline compound absorber materials on large area substrates using low-cost methods.

Group IIB-VIA compound semiconductors comprising some of the Group IIB (Cd, Zn, Hg) and Group VIA (O, S, Se, Te, Po) materials of the periodic table are excellent absorber materials for thin film solar cell structures. Especially CdTe has proved to be a material that can be used in manufacturing high efficiency solar panels at a cost below $1/W. In a good quality CdTe solar cell absorber film, the Cd/Te molar ratio needs to be near unity.

FIGS. 1A and 1B show the two different structures employed in CdTe based solar cells. FIG. 1A is a “super-strate” structure, wherein light enters the active layers of the device through a transparent sheet 11. The transparent sheet 11 serves as the support on which the active layers are deposited. In fabricating the “super-strate” structure 10, a transparent conductive layer (TCL) 12 is first deposited on the transparent sheet 11. Then a junction partner layer 13 is deposited over the TCL 12. A CdTe absorber film 14, which is a p-type semiconductor film, is next formed on the junction partner layer 13. Then an ohmic contact layer 15 is deposited on the CdTe absorber film 14, completing the solar cell. As shown by arrows 18 in FIG. 1, light enters this device through the transparent sheet 11. In the “super-strate” structure 10 of FIG. 1A, the transparent sheet 11 may be glass or a material (e.g., a high temperature polymer such as polyimide) that has high optical transmission (such as higher than 80%) in the visible spectra of the sun light. The TCL 12 is usually a transparent conductive oxide (TCO) layer comprising any one of; tin-oxide, cadmium-tin-oxide, indium-tin-oxide, and zinc-oxide which are doped to increase their conductivity. Multi layers of these TCO materials, both doped or undoped, as well as their alloys or mixtures may also be utilized in the TCL 12. The junction partner layer 13 is typically a CdS layer, but may alternately be a compound layer such as a layer of CdZnS, ZnS, ZnSe, ZnSSe, CdZnSe, etc. The ohmic contact 15 may comprise highly conductive metals such as Mo, Ni, Cr, Ti, Al, metal nitrides, or a doped transparent conductive oxide such as the TCOs mentioned above. The rectifying junction, which is the heart of this device, is located near an interface 19 between the CdTe absorber film 14 and the junction partner layer 13.

FIG. 1B depicts a “sub-strate” structure, wherein the light enters the device through a transparent conductive layer deposited over the CdTe absorber which is grown over a substrate. In the “sub-strate” structure 17 of FIG. 1B, the ohmic contact layer 15 is first deposited on a sheet substrate 16, and then the CdTe absorber film 14 is formed on the ohmic contact layer 15. This is followed by the deposition of the junction partner layer 13 and the transparent conductive layer (TCL) 12 over the CdTe absorber film 14. As shown by arrows 18 in FIG. 1B, light enters this device through TCL 12. There may also be finger patterns (not shown) on the TCL 12 to lower the series resistance of the solar cell. The sheet substrate 16 does not have to be transparent in this case. Therefore, the sheet substrate 16 may comprise a sheet or foil of metal, glass or polymeric material.

The CdTe absorber film 14 of FIGS. 1A and 1B may be formed using a variety of methods. For example, U.S. Pat. No. 4,388,483 granted to B. M. Basol et al., describes the fabrication of a CdS/CdTe solar cell wherein the thin CdTe film is grown by a cathodic compound electrodeposition technique at low electrolyte temperatures, and then the as-deposited n-type CdTe film is type-converted to p-type through a high temperature annealing step to form the rectifying junction with an underlying CdS layer. The compound electrodeposition or electroplating technique typically uses acidic aqueous electrolytes and forms high quality rectifying junctions after the type-conversion step, yielding high quality solar cells.

Present inventions provide methods and apparatus for the control of properties of electrodeposited Group IIB-VIA compound layers, such as CdTe thin films, in a manufacturing environment.

### BRIEF DESCRIPTION OF THE DRAWINGS

FIG. 1A is a cross-sectional view of a prior-art CdTe solar cell with a “super-state” structure.

FIG. 1B is a cross-sectional view of a prior-art CdTe solar cell with a “sub-strate” structure.

FIG. 2 shows an electrodeposition system with a Group VIA material dosing system.

FIG. 3 shows top view of an exemplary CdTe electrodeposition system with multiple deposition chambers.

FIG. 3A shows a cross sectional side view of the system of FIG. 3 taken across “W-W” plane.

FIG. 3B shows a cross sectional side view of the system of FIG. 3 taken across “Y-Y” plane.

FIG. 4 shows a cross sectional side view of an electrolyte tank and a deposition chamber with two electrolyte feed lines.

### DETAILED DESCRIPTION OF THE INVENTION

In general, the present invention forms high quality Group IIB-VIA compound films, such as CdTe films at high yield in a manufacturing environment using an electrodeposition technique. The electrodeposition process is carried out of acidic solutions (also referred to as baths or electrolytes) with a pH range of 1-3. The plating solutions or electrolytes may comprise a high concentration of the Group IIB material and a low concentration of the Group VIA material. For example, for CdTe electrodeposition, an electrodeposition electrolyte may comprise>0.1M (larger than 0.1 molar) cadmium and only 0.00001-0.001M tellurium.

To keep the tellurium to cadmium molar ratio (i.e. Te/Cd ratio) in an electrodeposited CdTe film near unity may be challenging since the composition of the film is a function of many factors, such as the tellurium concentration in the bath, mass transfer of the electrolyte onto the surface of the workpiece over which the CdTe film is being plated, the deposition potential, the temperature of the electrolyte, and the quasi rest potential (QRP). QRP is the potential of the surface of the depositing CdTe film with respect to the plating solution under open circuit conditions, i.e. no current flowing through the workpiece, which is the cathode. In laboratory scale work carried out of small plating vessels, it is customary to control the composition of the depositing CdTe film through QRP measurements (see, for example, Panicker et al., Journal of Electrochemical Society, vol. 125, page. 566). This is accomplished by terminating the deposition process at certain time intervals by cutting off the cathodic deposition current, and measuring the voltage of the CdTe film surface deposited on the cathode with respect to a reference electrode dipped in the plating electrolyte. The deposition potential applied to the cathode is then adjusted to keep the QRP value within a predetermined range with respect to a reference electrode such as an Ag—AgCl reference electrode or standard calomel electrode. In a large scale manufacturing approach, many pieces of substrates need to be coated with CdTe film at the same time, preferably using a single deposition chamber. This way cost of manufacturing may be kept low. Controlling all the variables listed above, and especially measuring and controlling QRP for every single substrate being coated with CdTe is not practical in such cases. Present inventions provide methods and hardware to achieve control of the quality of electrodeposited Group IIB-VIA compound layers, such as CdTe films, in manufacturing environments.

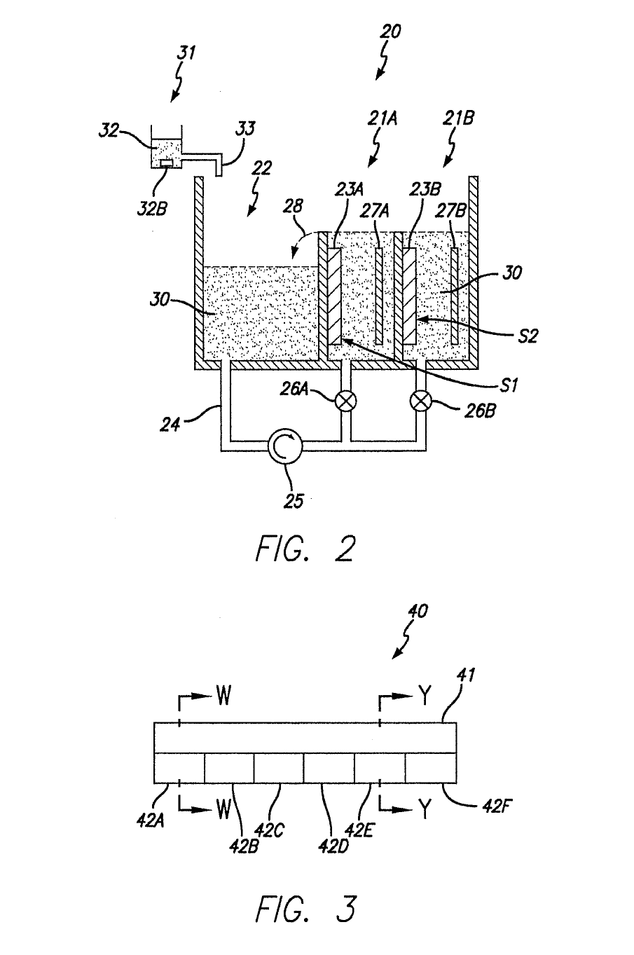

FIG. 2 shows an exemplary electrodeposition system 20 comprising a first plating cell 21A, a second plating cell 21B, and a solution or electrolyte tank 22. Group IIB-VIA compound layers may be electrodeposited using the system 20 of FIG. 2. We will from now on describe various embodiments of the inventions using CdTe as an example of a Group IIB-VIA material. It should be noted that the methods and apparatus described may be adapted for the electrodeposition of other Group IIB-VIA materials including, but not limited to, zinc telluride, mercury telluride, cadmium zinc telluride, cadmium mercury telluride, zinc mercury telluride, cadmium selenide, zinc selenide, etc. It should be noted that the exemplary electrodeposition system 20 has two plating cells. It is possible to add more plating cells to this system and thus have a capability to process tens of, even hundreds of, workpieces at the same time.

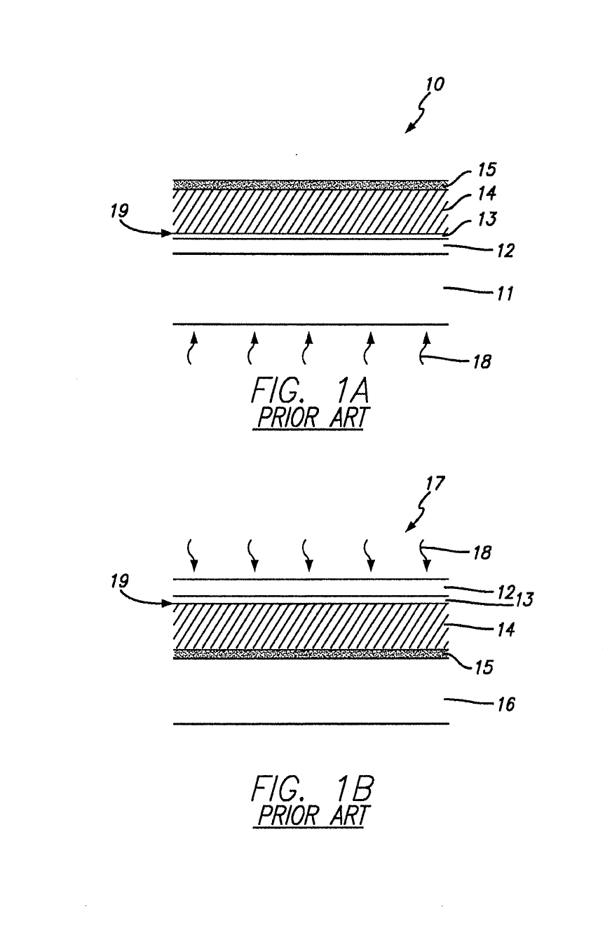

Referring back to FIG. 2, CdTe films may be electrodeposited onto a surface “S1” of a first workpiece 23A, and onto a surface “S2” of a second workpiece 23B, placed into an electrolyte 30 filling the first plating cell 21A, and the second plating cell 21B, respectively. It should be noted that the first workpiece 23A or the second workpiece 23B may comprise a transparent sheet, a transparent conductive layer and a junction partner layer as depicted in FIG. 1A, in which case the surface “S1” or the surface “S2” would be the exposed surface of the junction partner layer. Alternately, the first workpiece 23A or the second workpiece 23B may comprise a sheet substrate and an ohmic contact layer as depicted in FIG. 1B, in which case the surface “S1” or the surface “S2” would be the exposed surface of the ohmic contact layer.

The electrolyte 30 may be fed into the first and second plating cells through a feed line 24 that connects the tank 22 with the plating cells 21A and 21B. A pump 25 may pull a portion of the electrolyte 30 out of the tank 22 and flow it into the first plating cell 21A through a first valve 26A and into the second plating cell 21B through a second valve 26B. One or more pumps may be used. After filling the first and the second plating cells, the electrolyte 30 may be returned into the tank 22 as shown by arrow 28. Other means and equipment, such as heaters, filters, etc., may also be used in the system 20 of FIG. 2 to heat up, clean and filter the electrolyte 30 as it circulates between the tank 22 and the plating cells. Alternately, the tank 22 may have an additional circulating loop (not shown) with another pump that may pump the electrolyte 30 out of the tank 22, circulate it through filters, etc. and then return it back to the tank 22.

The two exemplary workpieces, i.e. the first workpiece 23A and the second workpiece 23B, may be coated with CdTe films in the first and second plating cells, respectively. During electroplating, using a power supply (not shown), a negative voltage may be applied to the first workpiece 23A (first cathode) with respect to a first anode 27A, and a similar voltage may be applied between the second workpiece 23B (second cathode) and a second anode 27B. This way CdTe films may be deposited on the surfaces “S1” and “S2” of the first and the second workpieces, respectively. In a preferred embodiment, the first workpiece 23A and the second workpiece 23B are electrically shorted together and connected to the negative terminal of a single power supply. Similarly, the first anode 27A and the second anode 27B may be electrically shorted together and connected to the positive terminal of the power supply. This way only one power supply can be used to provide voltage to the first and second workpieces with respect to the first and second anodes. During CdTe deposition, the voltage is kept constant, and the deposition current flowing through each workpiece is measured and monitored. It should be noted that the power supply may be a potentiostat, in which case, a reference electrode may be dipped into the solution 30 and the voltage of the cathode(s) may be controlled with respect to the reference electrode. It should also be noted that the electrical connections to the anode(s) and cathode(s) are not shown in FIG. 2 to simplify the drawing.

As discussed before, the properties of an electrodeposited CdTe layer may depend on various parameters of the electrodeposition process. These parameters include current, voltage, temperature, electrolyte flow, and bath composition. While investigating the interdependencies between these parameters and the CdTe film quality, the present inventor determined that best repeatable results in a manufacturing environment could be achieved if the deposition current and the bath composition are selected as the two variables, the deposition current being the “monitored variable” and the Group VIA material concentration of the bath being the “adjusted variable”. Accordingly, in an embodiment of the present inventions, the deposition current passing through at least one of the cathodes (i.e. the first workpiece 23A and the second workpiece 23B) is continually or periodically monitored during CdTe electrodeposition, and Te species are added into the electrolyte to keep the deposition current in a pre-determined range. For example, the deposition current density for a good quality CdTe layer may be in a range of 0.05-0.5 mA/cm² depending on the size of the workpiece (lower current densities being more appropriate for larger workpieces). Let us assume that the predetermined current density is 0.1 mA/cm² and that the allowed variation for this value is 10%. In this case, the electrodeposition process would be initiated under constant voltage mode and the deposition current or current density would be monitored. As the CdTe film is formed over the workpiece, the Te concentration in the bath would be depleted and the deposition current density would start to go down from the initial value of 0.1 mA/cm². Once the current density value falls below the allowable value of 0.09 mA/cm², an electrical signal may be sent by a control circuit or computer to a dosing system 31 containing a Te source 32. The dosing system 31 may then dispense a predetermined amount of the Te source into the tank 22 through a nozzle 33. The Te source 32 may be in the form of a liquid or solid. A preferred form of the Te source is TeO₂ particles 32A dispersed in a liquid, preferably water, as shown in FIG. 2. Alternately, the pH of the liquid may be adjusted to be equal to the pH of the electrolyte. A stirring mechanism 32B may be used in the dosing system 31 to keep the TeO₂ particles well dispersed all the time. Alternately, the stirring mechanism 32B helps to dissolve the TeO₂ particles in case the pH of the liquid is adjusted to a low value, which may be in the range of 1-3, preferably in the range of 1-2. After the predetermined amount of the Te source 32 is dispensed into the tank 22 and mixed with the electrolyte 30, the deposition current would start to rise to the acceptable level. This process of “sensing the deposition current decline, determining if and when the Te source addition is needed, and adding the Te source into the electrolyte” is repeated until a predetermined thickness (such as 1-2 um) of a CdTe film with uniform composition is obtained. Since the deposition current density is kept constant at a fixed deposition potential by controlling the Te content of the electrolyte, the resulting CdTe film has the desired composition with Cd/Te molar ratio near 1.0.

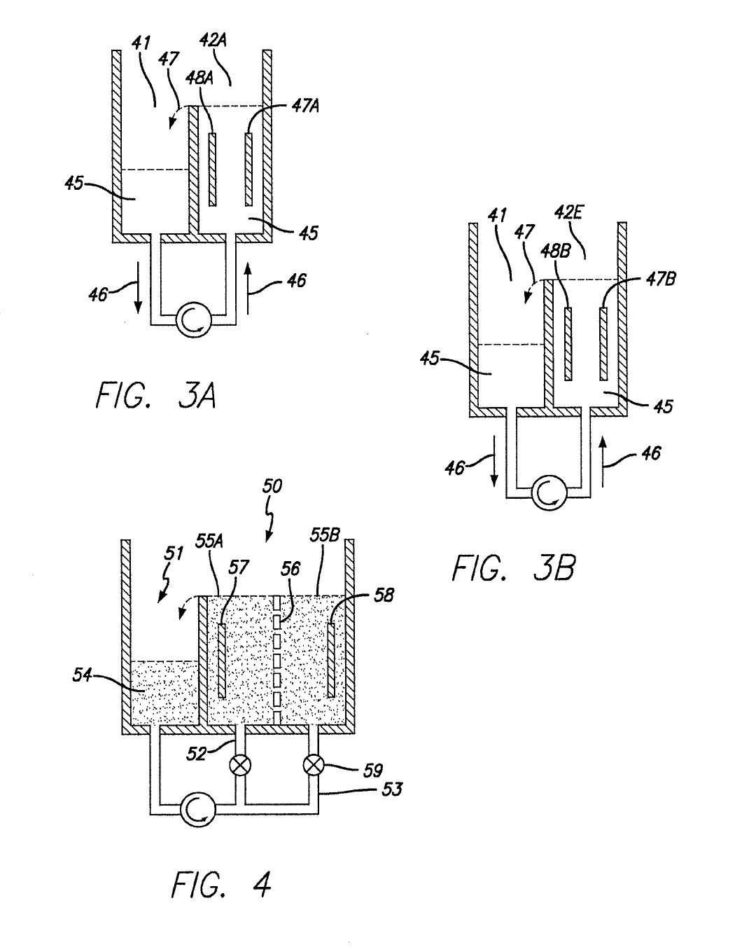

In another embodiment, controlled amounts of tellurium species are added into the electrolyte or plating bath of a multi cell or multi chamber electrodeposition system, from a predetermined number of anodes placed in a predetermined number of the plating cells or chambers. CdTe electrodeposition process requires six (6) electrons, two (2) electrons for the reduction of dissolved cadmium species in the electrolyte into Cd on the cathode surface, and four (4) electrons for the reduction of dissolved tellurium species in the electrolyte into Te on the cathode surface. To keep the amount of dissolved tellurium species (such as HTeO₂⁺ ions) in the electrolyte relatively constant during the electrodeposition process and thus keep the deposition current values relatively constant, a deposition system 40 shown in FIG. 3 may be used. The deposition system 40 of FIG. 3 is viewed from the top and it comprises multiple chambers 42A, 42B, 42C, 42D, 42E and 42F, within which CdTe may be electrodeposited on multiple workpieces. The chambers are positioned alongside an elongated tank 41 so that a plating solution may be circulated between the elongated tank 41 and the chambers. The deposition chambers of FIG. 3 may be of two different types. For example, the deposition chambers 42A and 42C may be “type I deposition chambers” and the deposition chambers 42B, 42D, 42E and 42F may be “type II deposition chambers”. Type I deposition chambers have anodes comprising an inert material such as iridium oxide, titanium, platinum, etc. or elemental cadmium. Type II deposition chambers, on the other hand, have anodes comprising tellurium. FIG. 3A and FIG. 3B show side cross sectional views taken along planes “W-W” and “Y-Y” of the type I chamber 42A and type II chamber 42E, respectively. As can be seen from these figures the plating solution 45 flows (shown by arrows 46) from the elongated tank 41 into the chambers 42A and 42E. The plating solution 45 then flows back into the elongated tank 41 as shown by arrows 47. The workpieces 47A and 47B are placed into the type I deposition chamber 42A and the type II deposition chamber 42E, respectively, for processing. The type I deposition chamber 42A contains a type I anode 48A, and the type II deposition chamber 42E contains a type II anode 48B. It should be noted that all type I deposition chambers (in this example; 42A and 42C) contain type I anodes and all type II deposition chambers (in this example; 42B, 42D, 42E and 42F) contain type II anodes. Type I anodes may comprise an inert material that does not dissolve into the electrolyte 45 during processing. Alternately, type I anodes may comprise cadmium which would dissolve into the electrolyte 45 during processing. Type II anodes, on the other hand, may comprise substantially pure Te so that Te species dissolve into the plating solution 45 during processing.

The number of type II deposition chambers in deposition systems of the present invention is double the number of type I deposition chambers. In the exemplary deposition system 40 of FIG. 3, the number of type II deposition chambers (42B, 42D, 42E and 42F) is four and the number of type I deposition chambers (42A and 42C) is two. By selecting this kind of configuration and keeping the CdTe deposition current substantially the same in all deposition chambers, the concentration of the tellurium species in the electrolyte may be kept relatively constant in a continuous operation. For example, in the deposition system 40 of FIG. 3, as CdTe is electroplated on the workpieces in the deposition chambers, type II anodes within the type II deposition chambers 42B, 42D, 42E and 42F, each would contribute to the electrolyte, through anodic dissolution, a concentration of Te species that is proportional to 6N, where N is the number of the type II deposition chambers, and 6 is the total number of electrons needed for CdTe formation. The type I anodes, would not contribute any Te species to the electrolyte during the process since they do not contain any Te. The consumption of Te in the system 40, on the other hand would be proportional 4M, where M is the total number of deposition chambers including the type I and type II deposition chambers, and 4 is the number of electrons needed at the cathode to reduce dissolved tellurium species to Te. As can be seen, in the exemplary system 40 of FIG. 3, 6N=6×4=24, and 4M=4×6=24. Therefore, all the Te produced by the type II anodes is consumed on the cathodes for CdTe deposition and there is no need to monitor the Te concentration of the plating solution or to have an external dosing system to add Te species into the electrolyte.

As specified before, in one aspect of the present invention the number of type II deposition chambers in a CdTe electrodeposition system is nearly double the number of type I deposition chambers. For example, a deposition system may have one type I and two type II deposition chambers, or fifty type I and one hundred type II deposition chambers, or one hundred and twenty type I and two hundred and forty type II deposition chambers, depending on the volume of manufacturing desired. Although FIG. 3 shows an example where the deposition chambers are along one side of the elongated tank, other designs comprising deposition chambers distributed all around the tank in various configurations are also possible. Since type II anodes introduce tellurium species into the electrolyte and the type I anodes do not, there may be a difference between the concentration of tellurium species within the type I and the type II deposition chambers, the electrolyte within the type II deposition chambers comprising a higher concentration of tellurium species. To avoid this problem, the flow rate of the electrolyte from the tank into the deposition chambers and back to the tank needs to be carefully selected. If the flow rate is very low, then the higher concentration of tellurium species in the type II deposition chambers would produce more Te-rich CdTe films, and the deposition current would also be higher at a given deposition potential. This is not acceptable in a manufacturing environment where the electrodeposited film quality needs to be similar for all deposition chambers. Therefore, the electrolyte flow needs to be adjusted so that the volume of the plating solution contained in each deposition chamber is replaced at least 10 times, preferably 20 times and most preferably at least 50 times during the deposition period. For example, in the deposition system 40 of FIG. 3, the volume of the plating solution 45 in each deposition chamber may be 5 gallons and the total deposition time may be 5 hours. In this example, the flow rate of the plating solution into each deposition chamber needs to be more than about 0.16 gallons/minute, preferably more than about 0.33 gallons/minute and more preferably more than about 0.8 gallons/minute. This way, most of the tellurium species generated by the type II anodes within the type II deposition chambers are quickly flown into the tank 41 (see for example arrow 47 in FIGS. 3A and 3B) and they get mixed up with the rest of the plating solution before the solution with the replenished tellurium species get distributed between all the deposition chambers.

In yet another embodiment, type II deposition chambers may employ separators or dividers. Use of such separators may reduce or even remove any constraints on the electrolyte flow rate described above. FIG. 4 shows an exemplary type II deposition chamber 50 next to a solution tank 51. Compared to the one depicted in FIG. 3B, the type II deposition chamber of FIG. 4 has two electrolyte feed lines, a first feed line 52 and a second feed line 53, that bring electrolyte 54 into two compartments separated by a porous divider 56. For this purpose, one or more pumps (only one shown) may be used. The first compartment 55A contains a type II anode 57, which comprises Te. The second compartment 55B contains a workpiece 58 which acts as a cathode. The porous divider 56 offers a high resistance to electrolyte flow between the first and second compartments. Valves 59 may be present on the first feed line 52 and the second feed line 53 to regulate the flow entering the first compartment 55A and the second compartment 55B. In this design the electrolyte flow rates up through the first compartment 55A and up through the second compartment 55B may be independently controlled during processing. Even if the tellurium species concentration increases in the first compartment 55A due to injection from the type II anode 57, this does not affect the CdTe deposition on the workpiece 58 in the second compartment 55B, because the second compartment 55B always receives a fresh mixed solution through the second feed line 53. The fresh mixed solution, as explained before is a mix of all solutions coming from all the type I deposition chambers and all the type II deposition chambers and thus contains the proper concentration of tellurium species. With the design of FIG. 4 a low electrolyte flow may be established in the second compartment 55B for CdTe electrodeposition and a high electrolyte flow may be established in the first compartment 55A to provide the tellurium species to the electrolyte 54 in the solution tank 51.

Although the present invention is described with respect to certain preferred embodiments, modifications thereto will be apparent to those skilled in the art.

1. A method of electrodepositing a Group IIB-VIA compound layer with a targeted thickness on a workpiece surface immersed in an electrolyte with a pH value comprising dissolved Group IIB ionic species and dissolved Group VIA ionic species, the method comprising:
immersing an anode into the electrolyte;
applying a negative voltage to the workpiece surface with respect to the anode;
measuring a value of a deposition current passing through the anode and the workpiece surface;
dispensing a source of Group VIA ionic species into the electrolyte to keep the value of the deposition current within a pre-determined range; and
repeating the steps of measuring and adding until the targeted thickness is reached.

2. The method of claim 1, wherein the source of Group VIA ionic species comprises solid particles.

3. The method of claim 2, wherein the solid particles are dispersed in a liquid.

4. The method of claim 3, wherein the liquid comprises water.

5. The method of claim 3, wherein a pH value of the liquid is configured to be substantially the same as the pH value of the electrolyte.

6. The method of claim 2, wherein the solid particles comprise tellurium oxide.

7. The method of claim 1, wherein the Group IIB-VIA compound layer comprises CdTe.

8. The method of claim 2, wherein the Group IIB-VIA compound layer comprises CdTe.

9. The method of claim 3, wherein the Group IIB-VIA compound layer comprises CdTe.

10. The method of claim 5, wherein the Group IIB-VIA compound layer comprises CdTe.

11. The method of claim 6, wherein the Group IIB-VIA compound layer comprises CdTe.
